(19) United States
(12) Patent Application Publication
(10) Pub. No.: US 2014/0126156 A1
(43) Pub. Date: May 8, 2014

(54) CIRCUIT MODULE

(71) Applicant: TAIYO YUDEN CO., LTD., Tokyo (JP)

(72) Inventors: Masaki NAGANUMA, Tokyo (JP); Hiroshi NAKAMURA, Tokyo (JP)

(73) Assignee: TAIYO YUDEN CO., LTD., Tokyo (JP)

(21) Appl. No.: 13/868,847

(22) Filed: Apr. 23, 2013

(30) Foreign Application Priority Data
Nov. 5, 2012 (JP) 2012-243469

(51) Int. Cl. H05K 1/02

(52) U.S. Cl. CPC H05K 1/0206
USPC 361/719; 361/720

(57) ABSTRACT

In a circuit module, a multilayer substrate has a core layer made of a metal, a filter device is stored in a storage portion of the core layer, the filter device and a power amp IC are arranged such that a parallel projection region of the filter device is completely covered by a parallel projection region of the power amp IC, and the power amp IC is connected to the upper surface (one surface in the thickness direction) of the core layer through a plurality of thermal vias provided in the multilayer substrate.

This application claims the benefit of Japanese Application No. 2012-243469, filed in Japan on Nov. 5, 2012, which is hereby incorporated by reference in its entirety.

### BACKGROUND OF THE INVENTION

1. Field of the Invention

The present invention relates to a circuit module in which a circuit including a filter device and a heat-generating electronic component such as a power amp IC is constructed.

2. Description of Related Art

Examples of arrangement of a filter device and a heat-generating electronic component such as a power amp IC in this type of circuit module include a configuration in which a filter device and a heat-generating electronic component are mounted side by side on one surface of a multilayer substrate in the thickness direction (see FIG. 3 of Patent Document 1 below, for example) and a configuration in which a filter device is embedded in a multilayer substrate and a heat-generating electronic component is mounted on one surface of the multilayer substrate in the thickness direction at a position that is immediately above the filter device (see FIGS. 1 to 4 of Patent Document 2 below, for example).

In the former configuration, heat generated in the heat-generating electronic component can be released to the outside from the other surface of the multilayer substrate in the thickness direction through a plurality of thermal vias provided in the multilayer substrate. However, in order to prevent heat from reaching the filter device from the heat-generating electronic component, it is necessary to have a sufficient distance between the filter device and the heat-generating electronic component. This makes a signal transmission line between the filter device and the heat-generating electronic component longer, which possibly causes problems such as noise mixing into the signal transmission line.

In the latter configuration, while it is possible to make the signal transmission line between the filter device embedded in the multilayer substrate and the heat-generating electronic component shorter than the former configuration, the thermal vias used in the former configuration cannot be used, and therefore, there is a possibility that problems such as erroneous operation of the filter device are caused by heat transferred from the heat-generating electronic component.

### RELATED ART DOCUMENTS

### Patent Documents

Patent Document 1: Japanese Patent Application Laid-Open Publication No. 2006-203652
Patent Document 2: Japanese Patent Application Laid-Open Publication No. 2007-312108

### SUMMARY OF THE INVENTION

An object of the present invention is to provide a circuit module in which problems of noise mixture and the like are not likely to occur in a signal transmission line between a filter device and a heat-generating electronic component and in which problems of erroneous operation of the filter device and the like due to heat transferred from the heat-generating electronic component are not likely to occur.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present invention provides a circuit module, including: a multilayer substrate; a filter device embedded in the multilayer substrate; and a heat-generating electronic component mounted on one surface of the multilayer substrate, wherein the filter device and the heat-generating electronic component construct a circuit, wherein the multilayer substrate has a core layer made of a metal, wherein the filter device is stored in a storage portion formed in the core layer, wherein the filter device and the heat-generating electronic component are positioned such that at least part of the filter device overlaps the heat-generating electronic component in a plan view, and wherein the heat-generating electronic component is connected to one surface of the core layer through a plurality of thermal vias provided in the multilayer substrate.

According to the present invention, it is possible to provide a circuit module in which problems of noise mixture and the like are not likely to occur in a signal transmission line between a filter device and a heat-generating electronic component and in which problems of erroneous operation of the filter device and the like due to heat transferred from the heat-generating electronic component are not likely to occur.

The above-mentioned objects, other objects, and features and effects for the respective objects of the present invention will be made apparent from the descriptions that follow and appended drawings.

### BRIEF DESCRIPTION OF THE DRAWINGS

FIG. 1 is a vertical cross-sectional view of a main part of a circuit module according to the present invention.

FIG. 2 is a diagram showing a positional relationship between a filter device and a power amp IC of FIG. 1.

### DETAILED DESCRIPTION OF THE PREFERRED EMBODIMENTS

### Configuration of Circuit Module

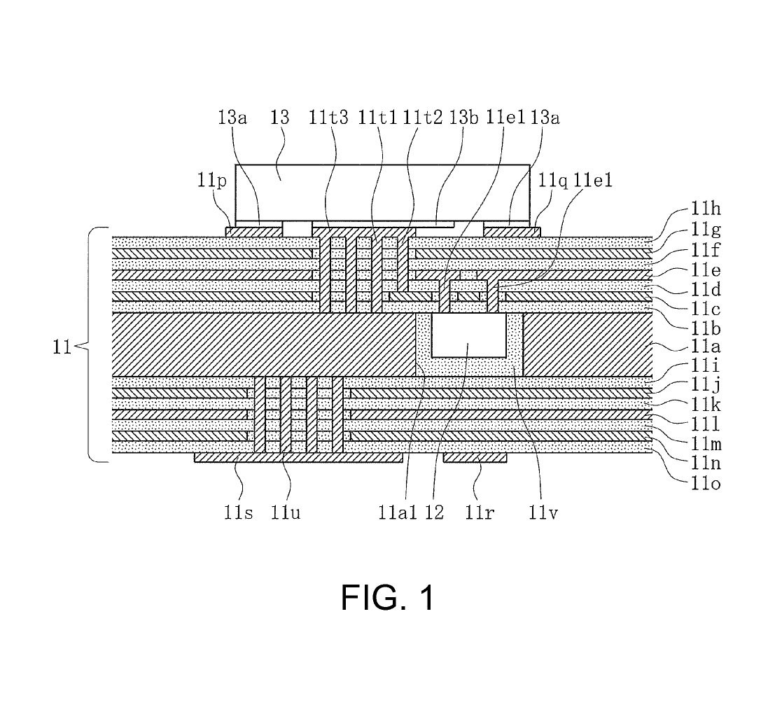

The circuit module shown in FIG. 1 includes a multilayer substrate 11, a filter device 12 embedded in the multilayer substrate 11, and a power amp IC (heat-generating electronic component) mounted on an upper surface (one surface in the thickness direction) of the multilayer substrate 11, and a circuit (high-frequency circuit) that includes the filter device 12 and the power amp IC 13 is constructed therein.

In the cross-sectional structure shown in FIG. 1, the multilayer substrate 11 includes: a core layer 11a that is made of a metal and that doubles as ground wiring; an insulating layer 11b, a conductive layer 11c, an insulating layer 11d, a conductive layer 11e, an insulating layer 11f, a conductive layer 11g, and an insulating layer 11h formed in this order on the upper surface (one surface in the thickness direction) of the core layer 11a; an insulating layer 11i, a conductive layer 11j, an insulating layer 11k, a conductive layer 11l, an insulating layer 11m, a conductive layer 11n, and an insulating layer 11o formed in this order on the lower surface (the other surface in the thickness direction) of the core layer 11a; signal pad 11p and ground pad 11q provided on the upper surface of the topmost insulating layer 11h; and signal pad 11r and ground pad 11s provided on the lower surface of the bottommost insulating layer 11o.

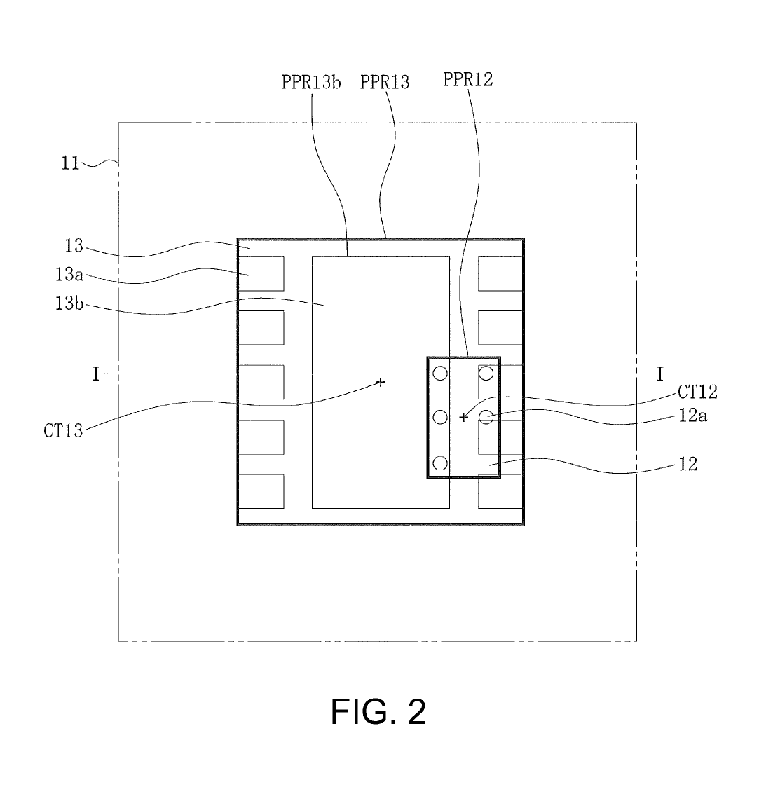

The multilayer substrate 11 also includes a plurality of (three in FIG. 1) thermal vias 11t1 reaching from the upper surface of the topmost insulating layer 11h to the upper surface of the core layer 11a and at least one (one in FIG. 1) thermal via 11t2 reaching from the upper surface of the topmost insulating layer 11h to the upper surface of the conductive layer 11c that is a conductive layer closest to the upper surface of the core layer 11a. These thermal vias are arranged at substantially even intervals. The respective thermal vias 11t1 and 11t2 are formed in a columnar shape with a substantially circular cross section, and the upper ends thereof are continuously formed with a pad 11t3. The pad 11t3 is provided on the upper surface of the topmost insulating layer 11h. The pad 11t3 is connected to a thermal pad 13b of the power amp IC 13 (see FIG. 2). The lower ends of the respective thermal vias 11t1 are connected to the upper surface of the core layer 11a, and the lower end of the thermal via 11t2 is connected to the upper surface of the conductive layer 11c that is ground wiring. The respective thermal vias 11t1 are not in contact with the conductive layers 11c, 11e, and 11g formed above the core layer 11a, and the thermal via 11t2 is not in contact with the conductive layers 11e and 11g formed above the core layer 11a.

Further, the multilayer substrate 11 has a plurality of (four in FIG. 1) second thermal vias 11u reaching from the lower surface of the bottommost insulating layer 11o to the lower surface of the core layer 11a. The respective second thermal vias 11u are arranged at substantially even intervals. The second thermal vias 11u are formed in a columnar shape with a substantially circular cross section. The respective upper ends thereof are connected to the lower surface of the core layer 11a, and the respective lower ends are connected to the ground pad 11s. The second thermal vias 11u are not in contact with the conductive layers 11j, 11l, and 11n formed below the core layer 11a. The positions (center position) of the plurality of second thermal vias 11u are closer to the left side of the multilayer substrate 11 (in a direction orthogonally intersecting with the thickness direction) than the position (center position) of a group of thermal vias constituted of the thermal vias 11t1 and 11t2.

Further, the multilayer substrate 11 has two conductor vias 11e1. The conductor vias 11e1 are extended from the conductive layer 11e that is second closest to the upper surface of core layer 11a, and are connected to two of a plurality of pads 12a (see FIG. 2) of the filter device 12 with the respective lower ends thereof. The core layer 11a has a storage portion 11a1 of a substantially rectangular cuboid shape formed so as to penetrate therethrough, and in the storage portion 11a1, the filter device 12 is stored. In a space between inner walls of the storage portion 11a1 and the filter device 12, an insulating member 11v is provided.

The core layer 11a, the respective conductive layers 11c, 11e, 11g, 11j, 11l, and 11n, the signal pads 11p and 11r, the ground pads 11q and 11s, the respective thermal vias 11t1 and 11t2, the pad 11t3 thereof, and the respective second thermal vias 11u are made of a metal such as copper or copper alloy. The thickness of the core layer 11a is in a range of 100-400 μm, for example. The thicknesses of the respective conductive layers 11c, 11e, 11g, 11j, 11l and 11n, the signal pads 11p and 11r, the ground pads 11q and 11s, and the pad 11t3 are in a range of 5-25 μm, for example. The diameters of the respective thermal vias 11t1 and 11t2, the respective second thermal vias 11u, and the respective conductor vias 11e1 are in a range of 10-80 μm, for example.

The respective insulating layers 11b, 11d, 11f, 11h, 11i, 11k, 11m, and 11o and the insulating member 11v are made of a synthetic resin such as an epoxy resin, polyimide, a bismaleimide triazine resin, or a material obtained by adding a reinforcing filler such as glass fiber to any of these resins. The thickness of the respective insulating layers 11b, 11d, 11f, 11h, 11i, 11k, 11m, and 11o is in a range of 10-30 μm, for example.

Although not shown in FIG. 1, the respective conductive layers 11c, 11e, 11g, 11j, 11l, and 11n have signal wiring lines and ground wiring lines patterned thereon in a two dimensional manner. Also, on the upper surface of the topmost insulating layer 11h, signal pads and ground pads other than the signal pad 11p and ground pad 11q are arranged in a two dimensional manner, and on the lower surface of the bottommost insulating layer 11o, signal pads and ground pads other than the signal pad 11r and ground pad 11s are arranged in a two dimensional manner.

In the cross-sectional structure shown in FIG. 1, the filter device 12 is an electronic component that has a function of outputting signals in a prescribed frequency band extracted from inputted signals, which is, for example, an elastic wave filter such as a SAW filter utilizing surface acoustic waves or a BAW filter utilizing bulk acoustic waves. The filter device 12 may be for transmission or for reception. The filter device 12 is formed in a substantially rectangular cuboid shape, and has five pads 12a on the upper surface thereof (see FIG. 2). The five pads 12a include an input pad, an output pad, and ground pads, and in FIG. 1, two of the five are connected to the lower ends of the respective conductor vias 11e1.

In the cross-sectional structure shown in FIG. 1, the power amp IC 13 is an electronic component that has a function of amplifying signals outputted from the filter device 12 or signals to be inputted to the filter device 12. The power amp IC is in a substantially rectangular cuboid shape that is larger than the filter device 12. The power amp IC has ten pads 13a on both ends of the lower surface, and in the center portion thereof, a thermal pad 13b larger than the pads 13a is provided (see FIG. 2). The ten pads 13a include an input pad, an output pad, ground pads, and power supply pads. In FIG. 1, two of the ten are connected to the signal pad 11p and the ground pad 11q, respectively. The thermal pad 13b is connected to the pad 11t3 that is formed so as to connect the upper ends of the respective thermal vias 11t1 and 11t2.

Below, the positional relationship between the filter device 12 and the power amp IC 13 will be explained with reference to FIG. 2. PPR12 of FIG. 2 represents a parallel projection region of the filter device 12, and CT12 represents the center of the parallel projection region PPR12. PPR13 represents a parallel projection region of the power amp IC 13, and CT13 represents the center of the parallel projection region PPR13. The line I-I of FIG. 2 indicates the cross-sectional position of FIG. 1.

Specific examples of dimensions of the filter device 12 and the power amp IC 13 shown in FIG. 2 are as follows: the filter device 12 is formed to be 1.2 mm long and 0.7 mm wide; and the power amp IC 13 is formed to be 3.0 mm long and 3.0 mm wide. The thickness of the core layer 11a is 0.34 mm, which is greater than the thickness of the filter device 12 (0.32 mm).

As shown in FIG. 2, the filter device 12 and the power amp IC 13 are arranged such that the parallel projection region PPR12 of the filter device 12 is completely covered by the parallel projection region PPR13 of the power amp IC 13.

More specifically, the size of the parallel projection region PPR12 of the filter device 12 is smaller than the size of the parallel projection region PPR13 of the power amp IC 13, and the center CT12 of the parallel projection region PPR12 of the filter device 12 does not coincide with the center CT13 of the parallel projection region PPR13 of the power amp IC 13. When comparing the parallel projection region PPR12 of the filter device 12 with a parallel projection region PPR13b of the thermal pad 13b of the power amp IC 13, the size of the parallel projection region PPR12 of the filter device 12 is smaller than the size of the parallel projection region PPR13b of the thermal pad 13b, and a part of the parallel projection region PPR12 of the filter device 12 overlaps with the parallel projection region PPR13b of the thermal pad 13b.

<Effects of the Circuit Module>

(Effect 1) In the circuit module described above, the multilayer substrate 11 has the core layer 11a made of a metal, the filter device 12 is stored in the storage portion 11a1 of the core layer 11a, the filter device 12 and the power amp IC 13 are arranged such that the parallel projection region PPR12 of the filter device 12 is completely covered by the parallel projection region PPR13 of the power amp IC 13, and the power amp IC 13 is connected to the upper surface (one surface in the thickness direction) of the core layer 11a through the plurality of thermal vias 11t1 provided in the multilayer substrate 11.

That is, because the filter device 12 is stored in the storage portion 11a1 of the core layer 11a made of a metal in the multilayer substrate 11, the signal transmission line between the filter device 12 and the power amp IC 13 can be minimized. Also, heat generated in the power amp IC 13 can be efficiently transferred to the core layer 11a made of a metal through the plurality of thermal vias 11t1 provided in the multilayer substrate 11, thereby making it possible to effectively release the heat from the end faces of the core layer 11a and the like. Thus, problems of noise mixture and the like are not likely to occur in the signal transmission line between the filter device 12 and the power amp IC 13, and problems of erroneous operation of the filter device 12 and the like due to heat transferred from the power amp IC 13 are not likely to occur.

(Effect 2) In the circuit module described above, the center CT12 of the parallel projection region PPR12 of the filter device 12 does not coincide with the center CT13 of the parallel projection region PPR13 of the power amp IC 13, and the size of the parallel projection region PPR12 of the filter device 12 is smaller than the size of the parallel projection region PPR13 of the power amp IC 13.

That is, by arranging the filter device 12 such that the parallel projection region PPR12 thereof is located near the edge of the parallel projection region PPR13 of the power amp IC 13, it is possible to maximize the number of the thermal vias 11t1 provided to transfer heat from the power amp IC 13 to the core layer 11a made of a metal. In other words, because heat can be transferred to the core layer 11a through the thermal vias 11t1 more efficiently, heat transfer from the power amp IC 13 to the filter device 12 can be more reliably mitigated.

(Effect 3) In the circuit module described above, the conductive layer 11c, which is the ground wiring, is provided between the upper surface (one surface in the thickness direction) of the multilayer substrate 11 and the upper surface (one surface in the thickness direction) of the core layer 11a, and the thermal via 11t2, which is in the same group as the plurality of thermal vias 11t1, is connected to the conductive layer 11c that is the ground wiring.

With this configuration, heat generated in the power amp IC 13 can be efficiently transferred to the core layer 11a made of a metal in the multilayer substrate 11 through the plurality of thermal vias 11t1, and released to the outside through the end faces and the like of the core layer 11a. Also, heat generated in the power amp IC 13 can be efficiently transferred to the conductive layer 11c that is the ground wiring through the thermal via 11t2, and released to the outside through the end faces and the like of the conductive layer 11c. That is, by transferring heat generated in the power amp IC 13 to both the core layer 11a made of a metal and the conductive layer 11c, the heat release efficiency can be improved as a whole.

(Effect 4) In the circuit module described above, the power amp IC 13 has the thermal pad 13b in the center portion of the lower surface thereof (surface facing the one surface of the multilayer substrate 11 in the thickness direction), and the thermal pad 13b is connected to the plurality of thermal vias 11t1 and the thermal via 11t2.

With this configuration, heat generated in the power amp IC 13 can be efficiently guided to the thermal pad 13b provided in the center of the lower surface thereof, and the guided heat can be transferred to the plurality of thermal vias 11t1 and the thermal via 11t2. This makes it possible to transfer heat from the power amp IC 13 to the core layer 11a made of a metal even more efficiently.

(Effect 5) In the circuit module described above, the lower surface (the other surface in the thickness direction) of the core layer 11a and the ground pad 11s provided on the lower surface (the other surface in the thickness direction) of the multilayer substrate 11 are connected through the plurality of second thermal vias 11u provided in the multilayer substrate 11.

That is, the heat transferred from the power amp IC 13 to the core layer 11a made of a metal through the plurality of thermal vias 11t1 can be transferred to the plurality of second thermal vias 11u, and can be released to the outside through the ground pad 11s. This makes it possible to improve the heat release efficiency as a whole.

(Effect 6) In the circuit module described above, the positions of the plurality of second thermal vias 11u are closer to the left side of the multilayer substrate (in the direction orthogonally intersecting with the thickness direction) than the position of a group of thermal vias constituted of the plurality of thermal vias 11t1 and the thermal via 11t2.

That is, even when the plurality of second thermal vias 11u are not aligned, the heat transferred to the core layer 11a made of a metal can be transferred to the ground pad 11s through the plurality of second thermal vias 11u, which improves a degree of freedom in designing the position of the ground pad 11s. Also, because the position of the ground pad 11s can be freely determined, it is possible to dispose the signal pad 11r within the parallel projection region PPR13 of the power amp IC 13 on the lower surface (the other surface in the thickness direction) of the multilayer substrate 11. As a result, a compact circuit module that does not have dead spaces can be obtained.

### MODIFICATION EXAMPLES OF CONFIGURATION OF THE CIRCUIT MODULE

### Modification Example 1

In the <Configuration of Circuit Module> above, the filter device 12 for transmission or reception was stored in the storage portion 11a1 of the core layer 11a made of a metal in the multilayer substrate 11, but it is also possible to store a similar filter device 12 having the pads 12 with different quantity, positions, and the like in the storage portion 11a1 of the core layer 11a. Also, a different type of filter device such as a duplexer having both a reception filter part and a transmission filter part, for example, may be stored in the storage portion 11a1 of the core layer 11a. Even with these configurations, effects similar to Effects 1 to 6 above can be achieved. The storage portion 11a1 of the core layer 11a was shown as a penetrating storage portion 11a1, but the storage portion 11a1 may be a recess that does not penetrate the core layer 11a. Even with this configuration, effects similar to Effects 1 to 6 above can be achieved. Further, in the above configuration, the power amp IC was mounted on the upper surface (one surface in the thickness direction) of the multilayer substrate 11, but it is also possible to mount a similar power amp IC having the pads 13a and 13b with different quantity, positions, and the like on the upper surface (one surface in the thickness direction) of the multilayer substrate 11. Alternatively, a heat-generating electronic component other than the power amp IC such as an RFIC (radio frequency integrated circuit) may be mounted on the upper surface (one surface in the thickness direction) of the multilayer substrate 11. Even with these configurations, effects similar to Effects 1 to 6 above can be achieved.

### Modification Example 2

In the <Configuration of Circuit Module> above, the filter device 12 and the power amp IC 13 were arranged such that the parallel projection region PPR12 of the filter device 12 is completely covered by the parallel projection region PPR13 of the power amp IC 13. However, the filter device 12 and the power amp IC 13 may be arranged such that a part of the parallel projection region PPR12 of the filter device 12 overlaps with the parallel projection region PPR13 of the power amp IC 13. Even with this configuration, effects similar to Effects 1 to 6 above can be achieved.

### Modification Example 3

In the <Configuration of Circuit Module> above, the center CT12 of the parallel projection region PPR12 of the filter device 12 does not coincide with the center CT13 of the parallel projection region PPR13 of the power amp IC 13, and the size of the parallel projection region PPR12 of the filter device 12 was smaller than the size of the parallel projection region PPR13 of the power amp IC 13. However, regardless of the size of the parallel projection region PPR12 of the filter device 12, as long as the center CT12 of the parallel projection region PPR12 of the filter device 12 does not coincide with the center CT13 of the parallel projection region PPR13 of the power amp IC 13, and at least a part of the parallel projection region PPR12 of the filter device 12 overlaps with the parallel projection region PPR13 of the power amp IC 13, effects similar to Effects 1 to 6 above can be achieved.

### Modification Example 4

In the <Configuration of Circuit Module> above, the conductive layer 11c that is ground wiring was provided between the upper surface (one surface in the thickness direction) of the multilayer substrate 11 and the upper surface (one surface in the thickness direction) of the core layer 11a, and the thermal via 11t2, which is in the same group as the plurality of thermal vias 11t1, was connected to the conductive layer 11c that is the ground wiring. However, even when the thermal via 11t2 is omitted from the group of the plurality of thermal vias 11t1 and the thermal via 11t2, effects similar to Effects 1 and 2 and Effects 4 to 6 above can be achieved.

### Modification Example 5

In the <Configuration of Circuit Module> above, the power amp IC 13 had the thermal pad 13b in the center of the lower surface (surface facing the one surface of the multilayer substrate 11 in the thickness direction), and the thermal pad 13b was connected to the plurality of thermal vias 11t1 and the thermal via 11t2. However, even with a configuration in which the thermal pad 13b is not provided in the power amp IC 13, and the plurality of thermal vias 11t1 and the thermal via 11t2 are directly connected to the power amp IC 13, effects similar to Effects 1 to 6 above can be achieved.

### Modification Example 6

In the <Configuration of Circuit Module> above, the lower surface (the other surface in the thickness direction) of the core layer 11a was connected to the ground pad 11s provided on the lower surface (the other surface in the thickness direction) of the multilayer substrate 11 through the plurality of second thermal vias 11u provided in the multilayer substrate 11, but even when the plurality of second thermal vias 11u are not provided, effects similar to Effects 1 to 4 and Effect 6 above can be achieved.

### Modification Example 7

In the <Configuration of Circuit Module> above, the positions of the plurality of second thermal vias 11u were closer to the left side of the multilayer substrate (in a direction orthogonally intersecting with the thickness direction) than the position of a group of thermal vias constituted of the plurality of thermal vias 11t1 and the thermal via 11t2. However, even when the positions of the plurality of second thermal vias 11u are substantially aligned with the position of the group constituted of the plurality of thermal vias 11t1 and the thermal via 11t2 in the direction orthogonally intersecting with the thickness direction of the multilayer substrate 11, as long as the size of the parallel projection region PPR12 of the filter device 12 is smaller than the size of the parallel projection region PPR13 of the power amp IC 13, and at least part of the parallel projection region PPR12 of the filter device 12 overlaps with the parallel projection region PPR13 of the power amp IC 13, effects similar to Effects 1 to 6 above can be achieved.

It will be apparent to those skilled in the art that various modification and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A circuit module, comprising:
a multilayer substrate;
a filter device embedded in the multilayer substrate; and
a heat-generating electronic component mounted on one surface of the multilayer substrate,
wherein the filter device and the heat-generating electronic component construct a circuit,
wherein the multilayer substrate has a core layer made of a metal, and the filter device is stored in a storage portion formed in the core layer,
wherein the filter device and the heat-generating electronic component are positioned such that at least part of the filter device overlaps the heat-generating electronic component in a plan view, and
wherein the heat-generating electronic component is connected to one surface of the core layer through a plurality of thermal vias provided in the multilayer substrate.

2. The circuit module according to claim 1, wherein a center of the parallel projection region of the filter device does not coincide with a center of the parallel projection region of the heat-generating electronic component.

3. The circuit module according to claim 1, wherein a size of the parallel projection region of the filter device is smaller than a size of the parallel projection region of the heat-generating electronic component.

4. The circuit module according to claim 1, wherein the multilayer substrate has ground wiring between one surface thereof and one surface of the core layer, and
wherein the plurality of thermal vias include at least one thermal via connected to the ground wiring.

5. The circuit module according to claim 1, wherein the heat-generating electronic component has a thermal pad in a center portion of a surface facing said one surface of the multilayer substrate, and the thermal pad is connected to the plurality of thermal vias.

6. The circuit module according to claim 1, wherein another surface of the core layer is connected to a ground pad provided on another surface of the multilayer substrate through a plurality of second thermal vias provided in the multilayer substrate.

7. The circuit module according to claim 6, wherein positions of the plurality of second thermal vias are not aligned with positions of the plurality of thermal vias in a plan view.

8. The circuit module according to claim 1, wherein the multilayer substrate has, in a plan view, a signal pad positioned within the heat-generating electronic component mounted on another surface.

9. The circuit module according to claim 1, wherein the heat-generating electronic component is a power amp IC.

10. The circuit module according to claim 2, wherein a size of the parallel projection region of the filter device is smaller than a size of the parallel projection region of the heat-generating electronic component.
